(19) United States
(12) Patent Application Publication
(10) Pub. No.: US 2022/0399208 A1
(43) Pub. Date: Dec. 15, 2022

(54) SUBSTRATE PROCESSING METHOD AND SUBSTRATE PROCESSING APPARATUS

(71) Applicant: Tokyo Electron Limited, Tokyo (JP)

(72) Inventors: Hirofumi TAKEGUCHI, Koshi City (JP); Kazuyoshi SHINOHARA, Koshi City (JP); Kosuke FUKUDA, Koshi City (JP)

(21) Appl. No.: 17/805,073

(22) Filed: Jun. 2, 2022

(30) Foreign Application Priority Data
Jun. 11, 2021 (JP) 2021-098106

(51) Int. Cl. H01L 21/67

(52) U.S. Cl. CPC H01L 21/6704; H01L 21/6715

(57) ABSTRACT

A substrate processing method includes: a first processing step of supplying a first processing liquid to a surface of a substrate under rotation to cover the surface of the substrate with a liquid film of the first processing liquid; and a second processing step of supplying a second processing liquid having a surface tension smaller than that of the first processing liquid to the surface of the substrate to cover the surface of the substrate with a liquid film of the second processing liquid by substituting the first processing liquid with the second processing liquid, wherein the second processing step includes: a first stage of simultaneously supplying both the first processing liquid and the second processing liquid to the surface of the substrate, and a second stage of supplying the second processing liquid to a central portion of the surface of the substrate without supplying the first processing liquid.

### CROSS-REFERENCE TO RELATED APPLICATION

This application is based upon and claims the benefit of priority from Japanese Patent Application No. 2021-098106, filed on Jun. 11, 2021, the entire contents of which are incorporated herein by reference.

### TECHNICAL FIELD

The present disclosure relates to a substrate processing method and a substrate processing apparatus.

### BACKGROUND

In manufacturing a semiconductor device, predetermined liquid processing is performed by supplying various processing liquids to a substrate in a state in which the substrate is held in a horizontal posture and rotated around a vertical axis by a spin chuck. Patent Document 1 discloses shifting from a rinsing process to a substitution process as follows. In the latter half of the rinsing process, in addition to supplying the rinsing liquid to the central portion of the substrate, the rinsing liquid is also supplied to the outer peripheral portion of the substrate. Thereafter, while continuing the supply of the rinsing liquid to the outer peripheral portion of the substrate, the supply of the rinsing liquid to the central portion of the substrate is stopped. At the same time, isopropyl alcohol (IPA) is supplied to the central portion of the substrate. Thereafter, the supply of the rinsing liquid to the outer peripheral portion of the substrate is stopped while the IPA is continuously supplied to the central portion of the substrate.

### PRIOR ART DOCUMENT

### Patent Document

Patent Document 1: Japanese Registration Patent No. 6118758

### SUMMARY

According to one embodiment of the present disclosure, there is provided a substrate processing method including: a first processing step of supplying a first processing liquid to a surface of a substrate under rotation to cover the surface of the substrate with a liquid film of the first processing liquid; and a second processing step of supplying, after the first processing step, a second processing liquid having a surface tension smaller than that of the first processing liquid to the surface of the substrate under rotation to cover the surface of the substrate with a liquid film of the second processing liquid by substituting the first processing liquid existing on the substrate with the second processing liquid, wherein the second processing step includes: a first stage of simultaneously supplying, to the surface of the substrate under rotation, the first processing liquid in addition to the second processing liquid, and a second stage of supplying, after the first stage, the second processing liquid to a central portion of the surface of the substrate under rotation without supplying the first processing liquid, and wherein, at least in a first period of the first stage, while maintaining a condition that a first radial distance from a rotational center of the substrate to a liquid landing point of the first processing liquid on the surface of the substrate is greater than a second radial distance from the rotational center of the substrate to a liquid landing point of the second processing liquid, both the first radial distance and the second radial distance are increased.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a horizontal cross-sectional view of a substrate processing apparatus according to an embodiment.

FIG. 2 is a vertical cross-sectional view illustrating an example of a processing unit included in the substrate processing apparatus of FIG. 1.

FIG. 3 is a schematic plan view illustrating some parts such as a liquid receiving cup, a nozzle, and a nozzle arm taken out from the processing unit of FIG. 2.

FIGS. 4A to 4F are schematic side views for explaining an example of operations of a drying liquid nozzle and a rinsing liquid nozzle in an IPA substitution step.

FIG. 5 is a graph for explaining an example of an operation of the processing unit in the IPA substitution step.

FIGS. 6A to 6F are schematic side views for explaining another example of the operations of the drying liquid nozzle and the rinsing liquid nozzle in the IPA substitution step.

FIG. 7 is a schematic vertical cross-sectional view illustrating some parts taken out from an embodiment in which an auxiliary nozzle is added to the processing units of FIGS. 2 and 3.

FIG. 8 is a schematic plan view illustrating some parts taken out from the processing unit of FIG. 7.

### DETAILED DESCRIPTION

An embodiment of a substrate processing apparatus will be described with reference to the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

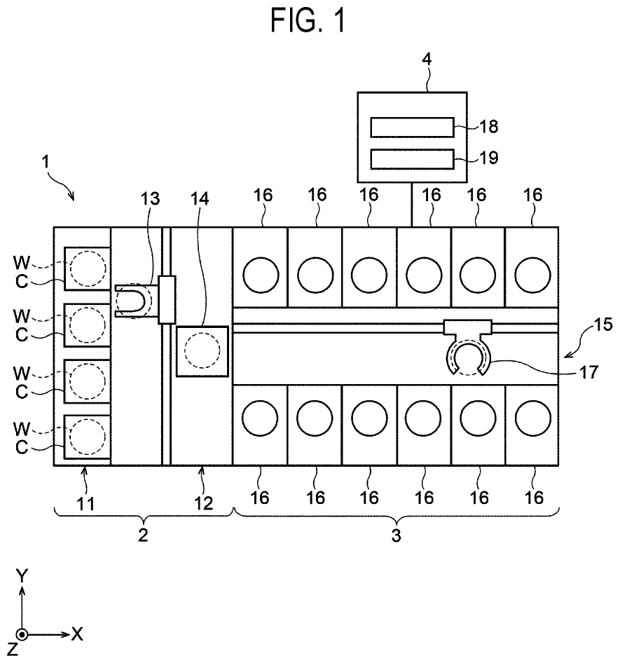

FIG. 1 is a schematic view illustrating a configuration of a substrate processing system according to an embodiment. In the following description, in order to clarify positional relationships, the X axis, the Y axis, and the Z axis, which are orthogonal to each other, are defined, and a positive direction of the Z axis is defined as a vertically upward direction.

As illustrated in FIG. 1, the substrate processing system 1 includes a carry-in/out station 2 and a processing station 3. The carry-in/out station 2 and the processing station 3 are provided adjacent to each other.

The carry-in/out station 2 includes a carrier placement part 11 and a transfer part 12. A plurality of carriers C, each of which accommodates a plurality of substrates W (in the present embodiment, semiconductor wafers) in a horizontal posture, are placed on the carrier placement part 11.

The transfer part 12 is provided adjacent to the carrier placement part 11 and includes therein a substrate transfer device 13 and a delivery part 14. The substrate transfer device 13 includes a wafer holding mechanism configured to hold the substrate W. In addition, the substrate transfer device 13 is capable of moving in the horizontal direction and the vertical direction and rotating about the vertical axis, and transfers substrates W between the carriers C and the delivery part 14 using the wafer holding mechanism.

The processing station 3 is provided adjacent to the transfer part 12. The processing station 3 includes a transfer part 15 and a plurality of processing units 16. The processing units 16 are arranged side by side on opposite sides of the transfer part 15.

The transfer part 15 includes therein a substrate transfer device 17. The substrate transfer device 17 includes a wafer holding mechanism configured to hold a substrate W. In addition, the substrate transfer device 17 is capable of moving in the horizontal direction and the vertical direction and rotating about the vertical axis, and transfers substrates W between the delivery part 14 and the processing units 16 using the wafer holding mechanism.

Each processing unit 16 performs predetermined substrate processing on the substrate W transferred thereto by the substrate transfer device 17.

The substrate processing system 1 includes a control device 4. The control device 4 is, for example, a computer, and includes a controller 18 and a storage 19. The storage 19 stores programs for controlling various processes executed in the substrate processing system 1. The controller 18 controls the operation of the substrate processing system 1 by reading and executing the programs stored in the storage 19.

In addition, such programs may be stored in a non-transitory computer-readable storage medium and installed on the storage 19 of the control device 4 from the storage medium. The computer-readable storage medium is, for example, a hard disk (HD), a flexible disk (FD), a compact disk (CD), a magneto-optical disk (MO), a memory card, or the like.

In the substrate processing system 1 configured as described above, first, the substrate transfer device 13 of the carry-in/out station 2 takes out the substrate W from the carrier C placed on the carrier placement part 11 and places the taken-out substrate W on the delivery part 14. The substrate W placed on the delivery part 14 is taken out from the delivery part 14 by the substrate transfer device 17 of the processing station 3 and carried into the processing unit 16.

After being processed by the processing unit 16, the substrate W carried into the processing unit 16 is carried out from the processing unit 16 and placed on the delivery part 14 by the substrate transfer device 17. The processed substrate W placed on the deliver part 14 is returned to the carrier C of the carrier placement part 11 by the substrate transfer device 13.

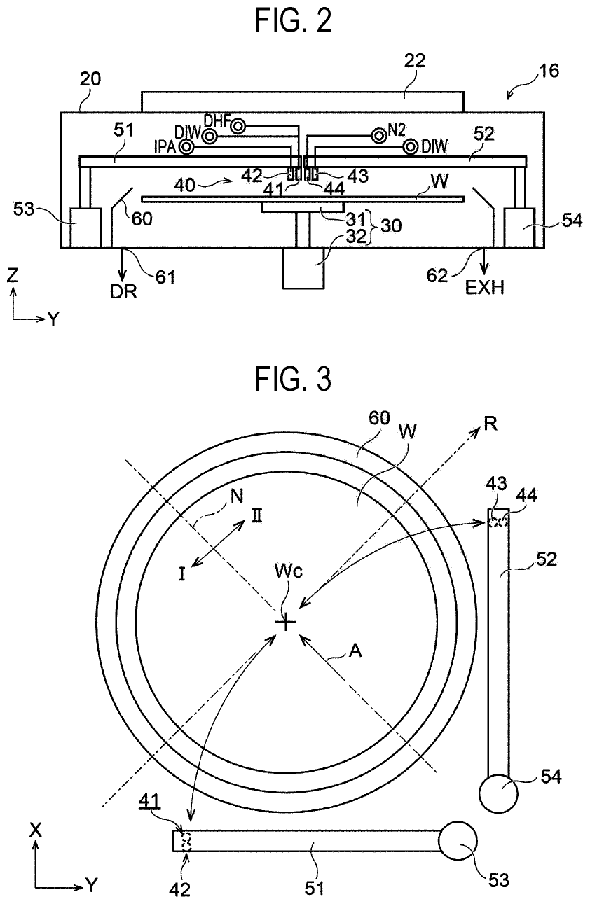

Next, a configuration of the processing unit 16 will be described with reference to FIG. 2.

As illustrated in FIG. 2, the processing unit 16 includes a chamber 20, a substrate holding/rotating mechanism 30, a processing fluid supplier 40, and a liquid receiving cup 60.

The chamber 20 accommodates the substrate holding/rotating mechanism 30, the processing fluid supplier 40, and the liquid receiving cup 60. The ceiling of the chamber 20 is provided with a fan filter unit (FFU) 21. The FFU 21 forms a down-flow within the chamber 20.

The substrate holding/rotating mechanism 30 includes a substrate holder (chuck part) 31 that holds the substrate W in a horizontal posture, and a rotary driver 32 that rotates the substrate holder 31 that holds the substrate W around a vertical axis. The substrate holder 31 may be of a type called a mechanical chuck that holds the peripheral edge of the substrate W by a gripping claw, or may be of a type called a vacuum chuck that vacuum-suctions the back surface of the substrate W. The rotary driving unit 32 includes an electric motor as a driving force generation source and is capable of rotating the substrate holder 31 at an arbitrary speed.

The processing fluid supplier 40 includes a plurality of processing fluid nozzles and one or more nozzle arms. In the illustrated embodiment, the plurality of processing fluid nozzles include at least a chemical liquid/rinsing liquid nozzle 41, a drying liquid nozzle 42, a rinsing liquid nozzle 43, and a gas nozzle 44. The chemical liquid/rinsing liquid nozzle 41 selectively ejects dilute hydrofluoric acid (DHF), which is an acidic chemical liquid, and pure water (DIW) as a rinsing liquid. The drying liquid nozzle 42 ejects a liquid having a lower surface tension than the rinsing liquid, preferably having higher volatility than the rinsing liquid, and preferably having a property that can be easily substituted with the rinsing liquid (e.g., compatibility), for example, isopropyl alcohol (IPA). The rinsing liquid nozzle 43 ejects DIW as a rinsing liquid. The gas nozzle 44 ejects a gas having a low humidity and a low oxygen concentration, for example, a drying gas such as a nitrogen gas. In addition to DIW, the rinsing liquid may be a functional water in which a trace amount of an electrolyte component is dissolved in DIW.

Each processing liquid nozzle is supplied with a processing fluid via a processing fluid supply mechanism (schematically indicated by double circles in FIG. 2). As is widely known in the art, the processing fluid supply mechanism may include a processing fluid source such as a tank or a factory resource, a supply line for a supplying processing fluid from the processing fluid source to a processing liquid nozzle, a flow rate control device such as a flow meter, an opening/closing valve, or a flow control valve provided in each of the supply line, and auxiliary equipment such as a filter and a heater. Each processing fluid supply mechanism may control the on/off of the ejection of the processing fluid from the corresponding processing fluid nozzle and the ejection flow rate of the processing fluid from the corresponding processing fluid nozzle.

A chemical liquid supply mechanism and a rinsing liquid supply mechanism as processing fluid supply mechanisms are connected to the chemical liquid/rinsing liquid nozzle 41, whereby a chemical liquid (DHF) or a rinsing liquid (DIW) may be selectively ejected from the chemical liquid/rinsing liquid nozzle 41.

In the illustrated embodiment, the processing fluid supplier 40 includes two nozzle arms, that is, a first nozzle arm 51 and a second nozzle arm 52, as the above-mentioned one or more nozzle arms. In the illustrated embodiment, the first nozzle arm 51 and the second nozzle arm 52 are configured to swing around swivel axes thereof extending in the vertical direction by arm driving mechanisms 53 and 54 provided at their respective base ends. The chemical liquid/rinsing liquid nozzle 41 and the drying liquid nozzle 42 are supported at the tip end of the first nozzle arm 51. The rinsing liquid nozzle 43 and the gas nozzle 44 are supported at the tip end of the second nozzle arm 52.

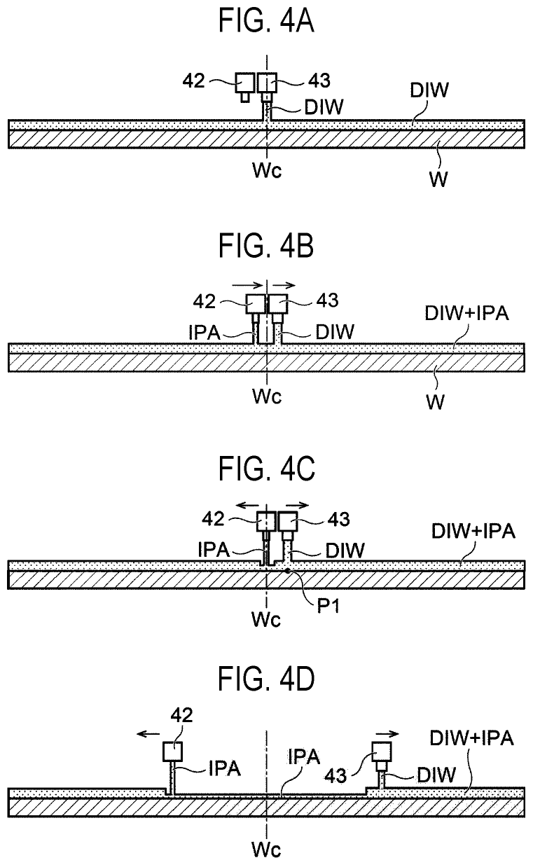

In the illustrated embodiment, the first nozzle arm 51 and the second nozzle arm 52 are installed such that the tip ends thereof (i.e., the processing fluid nozzles (the chemical liquid/rinsing liquid nozzle 41, the drying liquid nozzle 42, the rinsing liquid nozzle 43 and the gas nozzle 44) supported thereon) are movable while drawing substantially the same arc-shaped trajectories, respectively, in a plan view. In the illustrated embodiment, all the trajectories of the tip ends of both nozzle arms 51 and 52 pass directly above a rotational center Wc of the substrate W. In the illustrated embodiment, since the positions of the swivel centers (positions of 53 and 54) of both nozzle arms 51 and 52 are slightly different from each other, the movement trajectories of the tip ends of both the nozzle arms 51 and 52 do not completely match, but may be regarded as substantially the same. The arrangement of the first nozzle arm 51 and the second nozzle arm 52 in FIG. 2 does not match the arrangement in FIG. 3, but this is because the ease of viewing the drawings is emphasized, and the arrangement in FIG. 3 is correct.

The processing unit 16 may be further provided with another nozzle arm. The nozzle arm is not limited to the swivel arm type illustrated in the drawings, and may be of a linear motion type that translates along a guide rail. When two swivel arm type nozzle arms are provided, both the nozzle arms may be provided such that the tip ends of both the nozzle arms draw movement trajectories that are point-symmetrical to each other with respect to the rotational center Wc of the substrate W in a plan view.

The liquid receiving cup 60 is provided to surround the substrate holder 31, and collects the processing liquid scattered from the rotating substrate W. The processing liquid collected by the liquid receiving cup 60 is discharged to the exterior of the processing unit 16 from the liquid drain port 61 provided in the bottom portion of the liquid receiving cup 60. An exhaust port 62 is also provided in the bottom portion of the liquid receiving cup 60, and the interior of the liquid receiving cup 60 is suctioned through the exhaust port 62.

Next, a series of liquid processing steps performed by the processing unit 16 will be described. The following steps are performed under the control of the control device 4. In an embodiment, a process recipe and a control program are stored in the storage 19 of the control device 4, and the control device 4 executes the control program to control the operation of each part of the processing unit 16 to execute the steps, which will be described later.

In the illustrated embodiment, the nozzles 41 to 43 for ejecting a processing liquid are installed on the arms 51 and 52 to eject the processing liquid directly downward. Therefore, in the following description, it means that the position of each of the nozzles 41 to 43 itself (specifically, the position of the ejection port of each nozzle) and the position of the “liquid landing point” of the processing liquid ejected from each of the nozzles 41 to 43 to the surface of the substrate W are the same. The nozzle for supplying a processing gas injects the processing gas diagonally downward (toward the peripheral edge of the substrate W).

In the following description, the term “liquid landing point” means an intersection of the center (the central axis of a column) of the liquid (a liquid column) ejected in a columnar shape from each of the nozzles 41 to 43 with the surface of the substrate W. When a nozzle ejects the liquid directly downward, the position of the nozzle (strictly speaking, the position of the central axis of the ejection port of the nozzle) and the position of the liquid landing point are the same (with respect to the horizontal position excluding the vertical position). In addition, the liquid ejected in a columnar shape from the nozzle spreads on the surface of the substrate W due to a force of collision at the moment when the liquid is landed on the surface of the substrate W. Therefore, even when the liquid landing point of the liquid ejected from a nozzle is located slightly outward from the rotational center Wc of the substrate W in the radial direction, since the liquid spreads due to the force of collision as described above, the liquid will cover the rotational center Wc of the substrate W. That is, in this case as well, the liquid ejected from the nozzle is supplied to the central portion of the substrate (a region near the rotational center Wc including the rotational center Wc of the substrate).

For convenience of explanation, the surface of the substrate W will be divided into two regions I and II in order to define the position of the nozzle itself and the position of the liquid landing point. As illustrated in FIG. 3, a region on the side of the first nozzle arm 51 with respect to a normal line N at the rotational center Wc of the nozzle movement trajectory (indicated by two arc-shaped arrows) in a plan view is defined as a region I, and a region on the side of the second nozzle arm 52 with respect to the normal line N is defined as a region II. The position of a nozzle (the position of the liquid landing point) is expressed by an R value. When the position of a nozzle (the position of a liquid landing point) is within the region I, the R value is represented by the radial distance from the rotational center Wc of the substrate W at a nozzle (the position of the liquid landing point)×(+1). When the position of a nozzle (the position of a liquid landing point) is within the region II, the R value is represented by the radial distance from the rotational center Wc of the substrate W at the position of a nozzle (the position of a liquid landing point)×(−1).

The substrate W continuously rotates without stopping from the start to the end of the following series of steps. The rotational speed of the substrate W is changed as needed.

### [Chemical Liquid Processing Step]

First, from the chemical liquid/rinsing liquid nozzle 41 supported on the first nozzle arm 51, DHF as the chemical liquid is ejected at a predetermined flow rate to land on the rotational center Wc (R=0 mm) of the rotating substrate W. The DHF that has landed on the center of the substrate W flows while spreading toward the peripheral edge of the substrate W due to a centrifugal force, and the entire surface of the substrate W is covered with the liquid film of the DHF. By continuing this state for a predetermined period of time, chemical liquid processing is performed on the surface of the substrate W.

### [Rinsing Step]

Next, the liquid ejected from the chemical liquid/rinsing liquid nozzle 41 is switched from DHF to DIW. That is, the DIW as the rinsing liquid is ejected from the chemical liquid/rinsing liquid nozzle 41 at a predetermined flow rate so that the DIW is landed on the center of the substrate W.

Subsequently, while maintaining the liquid landing point of the DHF from the chemical liquid/rinsing liquid nozzle 41 at the rotational center Wc (R=0 mm), the rinsing liquid nozzle 43 supported on the second nozzle arm 52 also ejects DIW to land on the position slightly separated from the rotational center Wc (e.g., R=−42 mm).

While continuing to eject DIW from the chemical liquid/rinsing liquid nozzle 41 and the rinsing liquid nozzle 43, the first nozzle arm 51 and the second nozzle arm 52 are simultaneously moved, the liquid landing point of the DIW from the chemical liquid/rinsing liquid nozzle 41 is moved to a position slightly separated from the rotational center Wc (e.g., R=+42 mm), and the liquid landing point of the DIW from the rinsing liquid nozzle 43 is moved to the rotational center Wc (R=0 mm). Thereafter, the ejection of the DIW from the chemical liquid/rinsing liquid nozzle 41 is stopped.

It is preferable to set the ejection flow rate per nozzle while both the chemical liquid/rinsing liquid nozzle 41 and the rinsing liquid nozzle 43 are simultaneously ejecting DIW to be smaller than the ejection flow rate per nozzle while only one of the chemical liquid/rinsing liquid nozzle 41 and the rinsing liquid nozzle 43 ejects DIW. When the two nozzles are brought close to each other and simultaneously supply liquid to the surface of the substrate W at a large flow rate, liquid splashing may occur due to interference between the liquids.

In the above-described rinsing step, the DIW that has landed on the center (or near the center) of the substrate W flows while spreading toward the peripheral edge of the substrate W due to a centrifugal force, and the entire surface of the substrate W is covered with the liquid film of DIW. Along with this, the DHF and a reaction product remaining on the surface of the substrate W are washed away by the DIW.

In the above-described embodiment, the nozzle for ejecting the rinsing liquid is changed from the chemical liquid/rinsing liquid nozzle 41 to the rinsing liquid nozzle 43 in the middle of the rinsing step. The reason for doing so is that the chemical liquid/rinsing liquid nozzle 41 and the drying liquid nozzle 42 are supported on the same nozzle arm. For example, when the drying liquid nozzle 42 is supported on another nozzle arm (e.g., a third nozzle arm), it is not necessary to perform the above-mentioned change operation, and the nozzle for ejecting the rinsing liquid may be only the chemical liquid/rinsing liquid nozzle 41.

### [IPA Substitution Step]

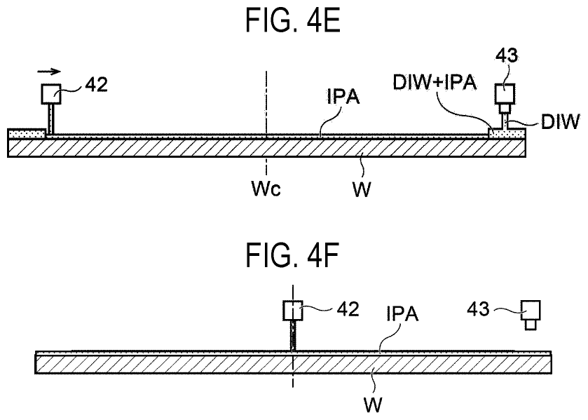

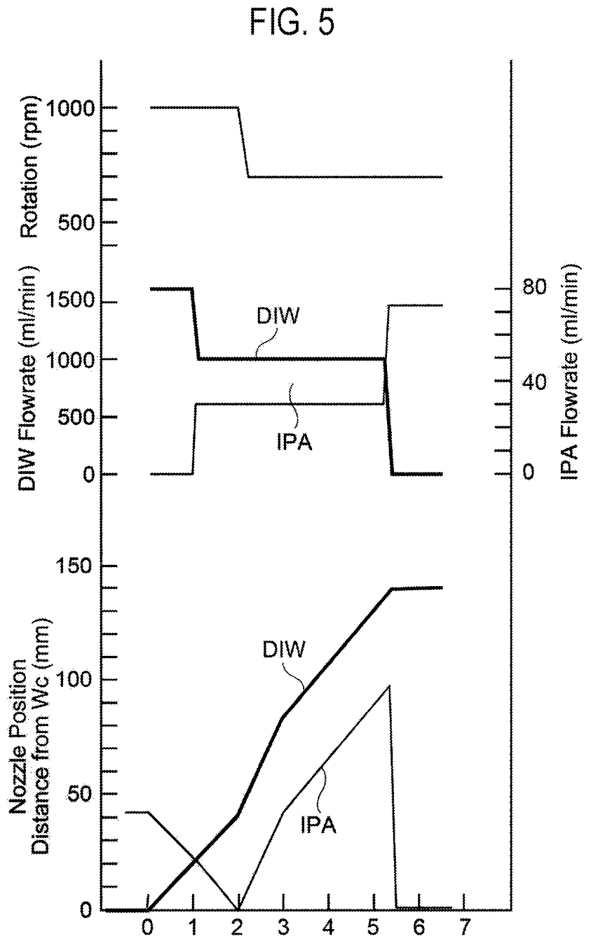

Next, an IPA substitution step of substituting DIW on the surface of the substrate W (including the inside of a recess of a pattern) with IPA will be described. In the description of the IPA substitution step, FIGS. 4A to 4A and FIG. 5 are also referred to.

FIGS. 4A to 4F illustrate the movements of the drying liquid nozzle 42 (supported on the first nozzle arm 51) and the rinsing liquid nozzle 43 (supported on the second nozzle arm 52) when viewed from the direction of arrow A in FIG. 3. The left sides of FIGS. 4A to 4F correspond to the region I (R value is positive), and the right sides of FIGS. 4A to 5F correspond to the region II (R value is negative). In FIGS. 4A to 4F, nozzles other than the nozzles 42 and 43 are not indicated for the sake of simplification of the drawings.

In the graph of FIG. 5, the upper stage represents the rotational speed of the substrate W, the middle stage represents the ejection flow rate of IPA from the drying liquid nozzle 42 (thin solid lines) and the ejection flow rate of DIW from the rinsing liquid nozzle 43 (thick solid line), and the lower stage represents the distance from the rotational center We of the liquid landing point of IPA from the drying liquid nozzle 42 (thin solid line) and the distance from the rotational center Wc of the liquid landing point of DIW from the rinsing liquid nozzle 43 (thick solid line), respectively, on the surface of the substrate W. In the lower stage, the absolute values of the above-mentioned R values are indicated (it does not matter whether the liquid landing point of liquid from the nozzle 42 or 43 is in the region I or the region II). In the graph of FIG. 5, the horizontal axis represents the elapsed time calculated from the start time of the IPA substitution step, and the unit is “second”.

When the rinsing liquid nozzle 43 ejects DIW toward the rotational center Wc of the substrate W for a predetermined period of time and the rinsing step is completed, the drying liquid nozzle 42 is brought close to the rinsing liquid nozzle 43 while maintaining the position of the rinsing liquid nozzle 43 and the ejection state of the DIW. At this time, the R value of the drying liquid nozzle 42 is, for example, −42 mm, and the R value of the rinsing liquid nozzle 43 is 0 mm. From the latter half of the rinsing step to this point, the DIW is continuously ejected from the rinsing liquid nozzle 43 at a relatively large ejection flow rate (e.g., 1,500 ml/min) (see FIG. 4A and the time point of the elapsed time of 0 sec in FIG. 5). The drying liquid nozzle 42 may be brought close to the rinsing liquid nozzle 43 while the DIW is being ejected from the rinsing liquid nozzle 43 in the latter half of the rinsing step.

Subsequently, the drying liquid nozzle 42 and the rinsing liquid nozzle 43 are simultaneously moved in the negative direction (preferably at the same moving speed of, for example, about 22 mm/sec), the drying liquid nozzle 42 is moved to a position directly above the center of rotation of the substrate W (the R value is 0 mm), and the rinsing liquid nozzle 43 is moved to a position slightly separated from the rotational center of the substrate W (e.g., a position at which the R value is −43 mm) (see FIGS. 4B and 4C, and the period of the elapsed time from 0 sec to 2 sec in FIG. 5).

In this movement process, when the distance of the liquid landing point of IPA from the drying liquid nozzle 42 from the rotational center Wc and the distance of the liquid landing point of DIW from the rinsing liquid nozzle 43 from the rotational center Wc (for example, when the R value of the liquid landing point of the IPA is +22 mm and the R value of the liquid landing point of the DIW is −20 mm) become substantially equal to each other, the ejection flow rate of the DIW from the rinsing liquid nozzle 43 is decreased from a first DIW ejection flow rate (e.g., 1,500 ml/min) to a second DIW discharge flow rate (for example, 1,000 ml/min) smaller than the first flow rate, and ejection of IPA is started from the drying liquid nozzle 42 at the first IPA ejection flow rate (e.g., 30 ml/min) (see FIG. 4B and the time point of the elapsed time of 1 sec in FIG. 5).

That is, at the time point of the elapsed time of 1 second, the first stage of the IPA substitution step in which both IPA and DIW are supplied to the substrate W is started. At this time, by starting the ejection of IPA before the drying liquid nozzle 42 reaches directly above the rotational center Wc of the substrate, it is possible to more reliably prevent the state in which the liquid does not exist in the region near the rotational center of the substrate W. This effect is that compared with the case in which IPA is not ejected until the drying liquid nozzle 42 reaches directly above the rotational center Wc of the substrate after the rinsing liquid nozzle 43 gets out of the position directly above the rotational center Wc of the substrate.

When the liquid landing point of the IPA from the drying liquid nozzle 42 coincides with the rotational center Wc, and the liquid landing point of the DIW from the rinsing liquid nozzle 43 reaches a position slightly separated from the rotational center Wc (for example, the position at which the R value is −42 mm), the rinsing liquid nozzle 43 is continuously moved in the negative direction, while the drying liquid nozzle 42 is moved in the positive direction by reversing the movement direction (see FIG. 4C and the time point of the elapsed time of 2 seconds in FIG. 5). That is, the rinsing liquid nozzle 43 and the drying liquid nozzle 42 are moved in opposite directions. Simultaneously or substantially simultaneously when the drying liquid nozzle 42 starts moving in the positive direction from the rotational center Wc toward the peripheral edge, the rotational speed of the substrate W is reduced (1,000 rpm→700 rpm). By reducing the rotational speed of the substrate W, it is possible to delay the timing at which the dried region starts to be formed in the vicinity of the rotational center Wc on the surface of the substrate W.

At this time, in order to always satisfy the condition that the distance of the liquid landing point of DIW from the rinsing liquid nozzle 43 from the rotational center Wc (the absolute value of the R value) is larger than the distance of the liquid landing point of IPA from the drying liquid nozzle 42 from the rotational center Wc (the absolute value of the R value), the rinsing liquid nozzle 43 and the drying liquid nozzle 42 are moved in opposite directions (see FIGS. 4C to 4E, and the time period of the elapsed time from 2 sec to 5.3 sec in the lower stage of FIG. 5).

At this time, as shown in the lower stage of the graph of FIG. 5, the moving speed of the rinsing liquid nozzle 43 and the moving speed of the drying liquid nozzle 42 may be maintained to be the same such that the difference between the absolute value of the R value of the liquid landing point of the DIW and the absolute value of the R value of the liquid landing point of the IPA is kept constant. The moving speed of the rinsing liquid nozzle 43 and the drying liquid nozzle 42 at this time may be set in the range of, for example, 20 to 50 mm/sec. The difference between the absolute value of the R value of the liquid landing point of the DIW and the absolute value of the R value of the liquid landing point of the IPA varies depending on the ejection flow rates of DIW and IPA, but is preferably within the range of about 40 mm to 90 mm. When the above-mentioned difference is too large, a liquid splashing prevention effect to be described later may be reduced. In addition, when the above-mentioned difference is too small, the DIW after landing and the IPA after landing may collide with each other, resulting in liquid splashing.

When the rinsing liquid nozzle 43 reaches a position near the peripheral edge of the substrate W (for example, the position at which the R value of the liquid landing point of DIW is −140 mm) (see FIG. 4E), the movement of the rinsing liquid nozzle 43 is stopped, and the ejection of DIW from the rinsing liquid nozzle 43 is also stopped. Simultaneously or substantially simultaneously with this, the drying liquid nozzle 42 is moved to a position directly above the rotational center Wc (R=0 mm) while continuously ejecting the IPA from the drying liquid nozzle 42. In addition, simultaneously or substantially simultaneously when the drying liquid nozzle 42 reaches the position directly above the rotational center Wc, the ejection flow rate of the IPA from the drying liquid nozzle 42 is increased to the second ejection flow rate (e.g., 75 ml/min) (see FIGS. 4E and 4F, and the elapsed time of 5.3 seconds or later in FIG. 5).

That is, at the time point of the elapsed time of 5.3 sec, the first stage of the IPA substitution step in which both IPA and DIW are supplied to the substrate W is completed, and the second stage of the IPA substitution step in which only IPA is supplied to the substrate W is initiated. Thereafter, by continuing the supply of IPA to the rotational center Wc of the substrate for a predetermined period of time, the second stage of the IPA substitution step is completed.

In the first stage of the IPA substitution step, an IPA liquid film is formed in the central region of the substrate W, and a liquid film of a mixed liquid of IPA and DIW is formed in the peripheral edge side (outer peripheral side) region. Strictly speaking, in the state of FIG. 4B (at the time point of the elapsed time of 1 sec), the rotational center Wc of the substrate W is covered with only the DIW spread to the rotational center Wc due to the force of landing after landing slightly radially outside from the rotational center Wc, and the region radially outside the liquid landing point of the IPA is covered with a mixed liquid of the IPA and the DIW. Thereafter, as illustrated in FIGS. 4C to 4E, with the passage of time, the region in which the inner IPA liquid film exists becomes wider, and the outer region in which the mixed liquid film exists becomes narrower. Then, in the second stage of the IPA substitution step, the entire surface of the substrate W is covered with the IPA liquid film.

That is, in the IPA substitution step, when viewed for each portion on the surface of the substrate W, the DIW in the portion is first replaced with a mixed liquid of IPA and DIW, and is then substituted with IPA.

In the IPA substitution step, the liquid landing point of the IPA from the drying liquid nozzle 42 moves away from the rotational center Wc toward the peripheral edge of the substrate W, and a dried region shall not be formed near the rotational center Wc of the surface of the substrate W until the liquid landing point of the IPA returns to the rotational center Wc again. This is because when an unintended dried region is generated, defects such as particles may occur in the region. In the actual operation of the apparatus, under the processing conditions exemplified in FIGS. 4A to 4F and FIG. 5, it has been confirmed that, even when the surface of the substrate W was hydrophobic, no dried region occurred near the rotational center Wc of the surface of the substrate and the processing was able to be performed without any problem. When drying occurs near the rotational center Wc, it can be dealt with by appropriately combining increasing the ejection flow rate of the IPA from the drying liquid nozzle 42, reducing the rotational speed of the substrate W, shortening the time until the liquid landing point of the IPA returns to the rotational center Wc again after the liquid landing point of the IPA is separated from the rotational center Wc, and the like.

In the above-described IPA substitution step, in order to always satisfy the condition that the distance from the rotational center Wc of the liquid landing point of the DIW from the rinsing liquid nozzle 43 is larger than the distance of the liquid landing point of the IPA from the drying liquid nozzle 42 from the rotational center Wc, the liquid landing points of the rinsing liquid nozzle 43 and the drying liquid nozzle 42 are moved outward in the radial direction. Therefore, it is possible to reduce the consumption of IPA, and even if the surface of the substrate W is hydrophobic, it is possible to prevent or significantly suppress liquid splashing. When liquid splashing occurs, the substrate W may be contaminated due to adhering of liquid droplets bounced off from the liquid receiving cup to the substrate W, adhering of fine droplets floating around the substrate W to the substrate W, and so on.

The reasons why the above-described effects are obtained will be explained below. It is assumed that, from the state of supplying DIW from the rinsing liquid nozzle to the center of the substrate, the ejection of the DIW from the rinsing liquid nozzle was stopped, and immediately after that, the ejection of IPA was started from the drying liquid nozzle toward the center of the substrate. In this case, before the liquid film of the IPA spreads to the peripheral edge of the substrate, the liquid film of the DIW may break at the peripheral edge of the substrate W and the peripheral edge may be exposed to air. This event is particularly likely to occur when the surface of the substrate W is hydrophobic. By increasing the ejection flow rate of IPA from the drying liquid nozzle and rapidly spreading the liquid film of IPA over the entire surface of the substrate, it is possible to suppress the occurrence of the above-mentioned event. However, the amount of expensive IPA used may increase.

By gradually bringing the liquid landing point of DIW ejected from the rinsing liquid nozzle closer to the peripheral edge of the substrate while continuing to eject IPA from the drying liquid nozzle toward the center of the substrate, the region covered with the IPA liquid film can be expanded toward the peripheral edge of the substrate while preventing the liquid film from being cut in the outer region of the substrate.

Through the experiment conducted by the present inventor(s), it was confirmed that, when the liquid landing point of DIW ejected from the rinsing liquid nozzle is gradually brought closer to the peripheral edge of the substrate W while the liquid landing point of IPA ejected from the drying liquid nozzle is maintained at the rotational center of the substrate, it is necessary to keep the ejection flow rate of the IPA relatively high. Specifically, in one experimental example, it was confirmed that when the ejection flow rate of IPA is lowered from a certain threshold value (50 ml/min), liquid splashing occurs when the liquid landing point of DIW is located outside a predetermined radial position (a position separated from the rotational center by about 85 mm).

Since the surface tension of IPA is significantly lower than that of DIW and the compatibility between IPA and DIW is high, the surface of the substrate on which a liquid film of IPA having a sufficient thickness is present may be regarded to be equivalent to the surface having high hydrophilicity. The thickness of the liquid film formed on the substrate by IPA ejected from the drying liquid nozzle and landed on the rotational center of the substrate becomes thinner toward the outside in the radial direction. When DIW ejected from the rinsing liquid nozzle at a relatively large ejection flow rate collides with a place in which an IPA liquid film is thin, the IPA liquid film is destroyed near the collision point, and when the DIW directly collides with the hydrophobic surface, liquid splashing occurs. It is possible to prevent liquid splashing by increasing the ejection flow rate of IPA from the drying liquid nozzle, but in this case as well, the amount of expensive IPA used increases.

In the above-described embodiment, in order to always satisfy the condition that the distance of the liquid landing point of DIW from the rinsing liquid nozzle 43 from the rotational center Wc of the DIW is larger than the distance of the liquid landing point of IPA from the drying liquid nozzle 42 from the rotational center Wc, both the liquid landing points are moved outward in the radial direction together. Therefore, regardless of the radial position of the liquid landing point of the DIW, since the thickness of the IPA liquid film is maintained at a sufficient thickness at the liquid landing point of the DIW, the occurrence of liquid splashing can be prevented.

### [Drying Step]

When the second stage of the IPA substitution step is completed (that is, when the IPA substitution step is completed), the drying step is executed. First, from the state of FIG. 4F, the position of liquid landing point of IPA is moved in the positive direction from the rotational center Wc of the substrate W toward the peripheral edge while continuing the ejection of IPA from the drying liquid nozzle 42. Simultaneously with the movement of the drying liquid nozzle 42, the gas nozzle 44 is also moved toward the peripheral edge of the substrate while ejecting nitrogen gas as a drying gas from the gas nozzle 44 supported on the second nozzle arm 52.

At this time, in order to always satisfy the condition that the position of the liquid landing point of IPA is located radially outside the position of the point at which the mainstream of nitrogen gas ejected from the gas nozzle 44 collides with the surface the substrate W, the drying liquid nozzle 42 and the gas nozzle 44 are moved in opposite directions. As a result, the circular dried region formed in the central portion of the substrate W gradually expands in the radial direction, and finally the entire surface of the substrate W is dried. It is preferable to move the drying liquid nozzle 42 and the gas nozzle 44 such that the mainstream of the gas is injected to a position slightly inside radially from the boundary between the dried region and the non-dried region (the region in which the IPA liquid film is present) on the surface of the substrate W.

Consequently, a series of processes for one substrate W is completed.

According to the above-described embodiment, it is possible to prevent the occurrence of liquid splashing while maintaining the state in which the liquid film continuously exists on the entire surface of the substrate W.

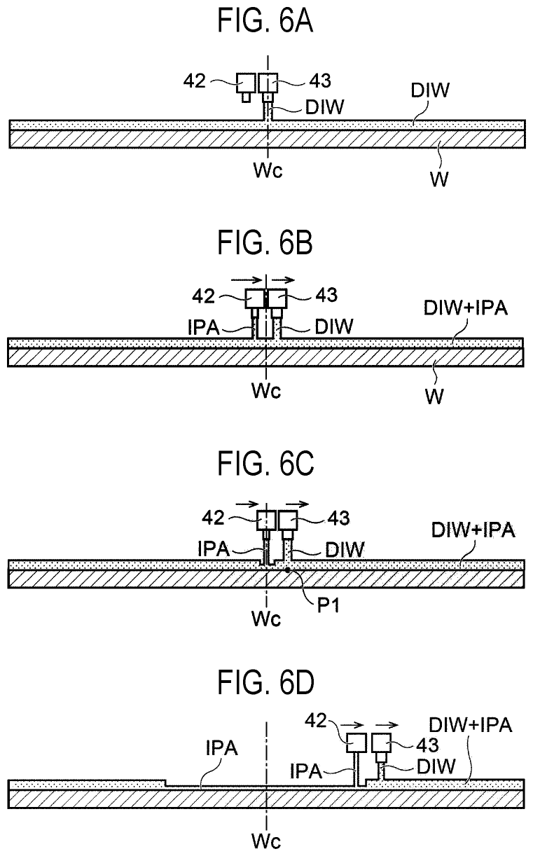

In the above-described embodiment, in the IPA substitution step, after the liquid landing point of the IPA from the drying liquid nozzle 42 coincides with the rotational center Wc, the drying liquid nozzle 42 is moved in the positive direction by reversing the moving direction (see FIGS. 4C to 4E), but the present disclosure is not limited thereto. As illustrated in FIG. 6C to 6E, the drying liquid nozzle 42 may be moved in the negative direction (that is, to the region II) in the same manner as the rinsing liquid nozzle 43.

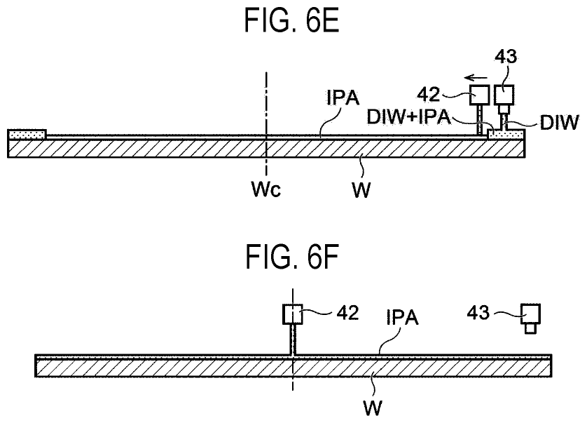

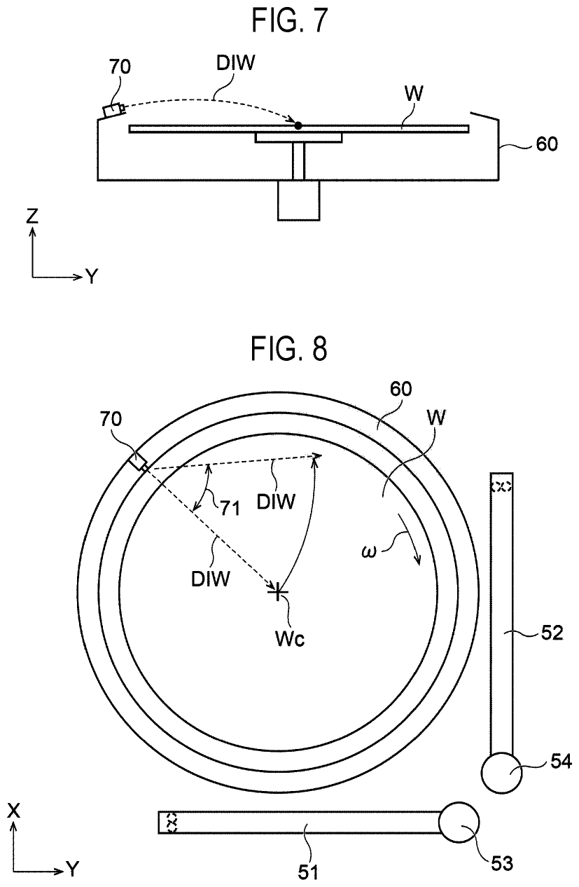

When IPA and DIW are simultaneously ejected in the IPA substitution step, the auxiliary nozzle 70 illustrated in FIGS. 7 and 8 may also be used as the nozzle for ejecting DIW. In this case, an auxiliary nozzle 70 is further added to the processing unit 16 in addition to the configuration illustrated in FIGS. 2 and 3. Therefore, the chemical liquid/rinsing liquid nozzle 41 or the rinsing liquid nozzle 43 may be used during a normal rinsing process.

The auxiliary nozzle 70 may be provided, for example, on the top surface of the liquid receiving cup 60 near the upper opening of the liquid receiving cup 60. As illustrated in FIG. 7, the auxiliary nozzle 70 ejects DIW to substantially draw a parabolic trajectory. The auxiliary nozzle 70 is capable of turning (swing) as indicated by the arrow 71, which makes it possible to change the liquid landing point of the DIW ejected from the auxiliary nozzle 70 (the radial position of the liquid landing point) on the substrate W. The turning range of the auxiliary nozzle 70 is determined in consideration of the rotating direction of the substrate W (the arrow w) such that the vector indicated by the DIW ejected from the auxiliary nozzle 70 generally follows the vector indicating the moving direction of the substrate W at the liquid landing point of the DIW (at least both vectors are not directed opposite to each other).

Since the surface tension of the IPA used in the IPA substitution step is significantly lower than that of the DIW, pattern collapse due to the surface tension is effectively suppressed in the subsequent drying step. IPA not only has a lower surface tension than DIW, but also has higher volatility than DIW and is easy to substitute with DIW. Therefore, IPA is widely used for covering the surface of a substrate immediately before a drying step in manufacturing a semiconductor device. It is possible to use a liquid other than IPA in place of IPA in the IPA substitution step as long as the liquid has the same properties as the IPA (particularly the low surface tension). In this case, the IPA substitution step is called a drying liquid substitution step. The drying step is not limited to the drying method described in the above-described embodiment, and for example, a supercritical drying method may also be used.

In the above-described embodiment, the substitution step of substituting DIW with IPA (IPA substitution step) has been described, but the technique used in the IPA substitution step may be widely used in a step of substituting a first processing liquid covering the surface of the substrate with a second processing liquid having a low surface tension than the first processing liquid. In this case as well, in substituting the first processing liquid with the second processing liquid, it is possible to prevent the occurrence of liquid splashing while maintaining the state in which the liquid film continuously exists on the entire surface of the substrate W.

According to the present disclosure, it is possible to reduce the amount of a low surface tension liquid used while preventing the generation of defects such as particles.

The embodiments disclosed herein should be considered to be exemplary in all respects and not restrictive. The above-described embodiments may be omitted, replaced, or modified in various forms without departing from the scope and spirit of the appended claims.

The substrate is not limited to a semiconductor wafer, and may be another type of substrate used in manufacturing semiconductor devices, such as a glass substrate or a ceramic substrate.

What is claimed is:

1. A substrate processing method comprising:
a first processing step of supplying a first processing liquid to a surface of a substrate under rotation to cover the surface of the substrate with a liquid film of the first processing liquid; and
a second processing step of supplying, after the first processing step, a second processing liquid having a surface tension smaller than that of the first processing liquid to the surface of the substrate under rotation to cover the surface of the substrate with a liquid film of the second processing liquid by substituting the first processing liquid existing on the substrate with the second processing liquid,
wherein the second processing step includes:
a first stage of simultaneously supplying, to the surface of the substrate under rotation, the first processing liquid in addition to the second processing liquid, and
a second stage of supplying, after the first stage, the second processing liquid to a central portion of the surface of the substrate under rotation without supplying the first processing liquid, and
wherein, at least in a first period of the first stage, while maintaining a condition that a first radial distance from a rotational center of the substrate to a liquid landing point of the first processing liquid on the surface of the substrate is greater than a second radial distance from the rotational center of the substrate to a liquid landing point of the second processing liquid, both the first radial distance and the second radial distance are increased.

2. The substrate processing method of claim 1, wherein, in the first period, a difference between the first radial distance and the second radial distance is maintained within a range of 40 mm to 90 mm.

3. The substrate processing method of claim 2, wherein, in the first period, the difference between the first radial distance and the second radial distance is kept constant.

4. The substrate processing method of claim 3, wherein a first position of the liquid landing point of the second processing liquid at a first time point in the first period is located at the rotational center of the substrate or located near the rotational center of the substrate to an extent that the rotational center of the substrate is covered with the second processing liquid.

5. The substrate processing method of claim 4, wherein a start time point of the first stage is a second time point before the first time point,
the first time point is a start time point of the first period,
the first stage has a second period, which is a primary period of the first stage, from the second time point to the first time point, and
both the liquid landing point of the first processing liquid and the liquid landing point of the second processing liquid on the surface of the substrate at the second time point are separated from the rotational center of the substrate, and then the liquid landing point of the second processing liquid moves to the first position by the first time point.

6. The substrate processing method of claim 5, wherein a second position of the liquid landing point of the first processing liquid on the surface of the substrate at least at an end of the first processing step, is located at the rotational center of the substrate or located near the rotational center of the substrate to an extent that the rotational center of the substrate is covered with the first processing liquid, and
when shifting from the first processing step to the first stage of the second processing step, the liquid landing point of the first processing liquid on the substrate is separated from the second position.

7. The substrate processing method of claim 6, wherein a supply flow rate of the first processing liquid in the first stage of the second processing step is smaller than a supply flow rate of the first processing liquid in the first processing step.

8. The substrate processing method of claim 7, wherein, in the second stage of the second processing step, the second processing liquid is continuously supplied to the central portion of the surface of the substrate.

9. The substrate processing method of claim 8, wherein a supply flow rate of the second processing liquid in the first stage of the second processing step is smaller than a supply flow rate of the second processing liquid in the second stage of the second processing step.

10. The substrate processing method of claim 9, wherein, when shifting from the first stage of the second processing step to the second stage, the liquid landing point of the second processing liquid is moved to the rotational center of the substrate or a position near the rotational center of the substrate to the extent that the rotational center of the substrate is covered with the second processing liquid.

11. The substrate processing method of claim 10, wherein a movement of the liquid landing point of the second processing liquid when shifting from the first stage to the second stage of the second processing step is performed before a dried region that is not covered with the liquid film occurs near the rotational center of the substrate.

12. The substrate processing method of claim 11, wherein, in the first stage of the second processing step, the first processing liquid is supplied from a first nozzle supported on a first nozzle arm, and the second processing liquid is supplied from a second nozzle supported on a second nozzle arm.

13. The substrate processing method of claim 12, wherein the first processing liquid is a rinsing liquid, and the second processing liquid is an organic solvent having a lower surface tension than the rinsing liquid.

14. The substrate processing method of claim 13, wherein the rinsing liquid includes pure water or functional water in which a trace amount of an electrolyte component is dissolved in the pure water.

15. The substrate processing method of claim 14, further comprising:
a chemical liquid processing step of supplying a chemical liquid to the surface of the substrate under rotation, wherein the first processing step is a rinsing step of washing away the chemical liquid by supplying a rinsing liquid as the first processing liquid to the substrate on which the chemical liquid processing step has been performed.

16. The substrate processing method of claim 1, wherein, in the first period, a difference between the first radial distance and the second radial distance is kept constant.

17. The substrate processing method of claim 1, wherein a first position of the liquid landing point of the second processing liquid at a first time point in the first period is located at the rotational center of the substrate or located near the rotational center of the substrate to an extent that the rotational center of the substrate is covered with the second processing liquid.

18. The substrate processing method of claim 1, wherein, in the second stage of the second processing step, the second processing liquid is continuously supplied to the central portion of the surface of the substrate.

19. The substrate processing method of claim 1, wherein a supply flow rate of the second processing liquid in the first stage of the second processing step is smaller than a supply flow rate of the second processing liquid in the second stage of the second processing step.

20. A substrate processing apparatus comprising;
a substrate holder configured to hold a substrate in a horizontal posture;
a rotary driver configured to rotate the substrate holder that holds the substrate around a vertical axis;
at least two nozzles provided to: supply a processing liquid to the substrate held by the substrate holder, supply a rinsing liquid to the substrate held by the substrate holder, supply a low surface tension liquid to the substrate held by the substrate holder, and simultaneously supply the rinsing liquid and the low surface tension liquid to the substrate held by the substrate holder;
at least one nozzle arm configured to move the at least two nozzles; and
a controller configured to control an operation of the substrate processing apparatus to execute the substrate processing method according to claim 1.
